(19) United States
(12) Patent Application Publication
(10) Pub. No.: US 2009/0295461 A1
(43) Pub. Date: Dec. 3, 2009

(54) DEVICE CONFIGURATION

(76) Inventors: Joshua de Cesare, Campbell, CA (US); Michael Smith, San Francisco, CA (US); Jonathan Jay Andrews, Mountain View, CA (US); Alan Gilchrist, Danville, CA (US); Hope Giles, Saratoga, CA (US)

Correspondence Address: APPLE INC./BSTZ;BLAKELY SOKOLOFF TAYLOR & ZAFMAN LLP, 1279 OAKMEAD PARKWAY, SUNNYVALE, CA, 94085-4040, US

(21) Appl. No.: 12/187,311

(22) Filed: Aug. 6, 2008

Related U.S. Application Data
(60) Provisional application No. 61/057,454, filed on May 30, 2008.

(51) Int. Cl. H03H 11/40; H05K 3/30

(52) U.S. Cl. 327/524; 29/832

(57) ABSTRACT

A process and apparatus for configuring one or more integrated circuits within a device in a manufacturing process is described. In an exemplary process, a device is manufactured by assembling a chip onto a board such as a printed circuit substrate and the chip is fused from power routed across the board to the chip. The power source for the fusing can be generated from the internal power supply on the board or received on a test point on the board itself or a connection interface (e.g. a USB interface) coupled to the board. In an exemplary apparatus, a device comprises a chip with a plurality of fuses that are used to configure the device and a board coupled to the chip, with the board capable of routing power from the board to the chip and the power is used to blow one or more of the plurality of fuses.

### RELATED APPLICATIONS

Applicant claims the benefit of priority of prior, co-pending provisional application Ser. No. 61/057,454, filed May 30, 2008.

### FIELD OF THE INVENTION

This invention relates generally to manufacturing a device and more particularly to configuration of a device late in the manufacturing process.

### BACKGROUND OF THE INVENTION

A chip or integrated circuit that is used a computer, mobile device, and other device can include one or more fuses (or other logic components) that are used to permanently configure the chip and/or the device containing the chip. A fuse is a hardware component of the chip, such as a thin wire or an electrically programmable structure such as a gate or set of gates, that can be permanently set in a fused state. Setting a fuse in the fused state is called configuring or “blowing” the fuse. Configuring a fuse can be accomplished using one of many approaches known in the art: sending an over-current or power across the fuse that breaks or destroys the fuse wire, using a laser to break the fuse wire, etc. In other implementations, the fuse can be set or programmed electronically without breaking a wire.

A device manufacturer can use the various fuses on the chip to permanently configure the device. A chip can have multiple fuses. Each fuse can be used individually to configure the device or can be used in groups of fuses to configure a particular part of the device. Fuses can also be nested to allow a fuse to be re-written a pre-determined number of times. For example, a logic inspects a set or paired fuses in a pre-determined order. The first fuse indicates to the logic that the second fuse is configured, without the logic inspecting the second fuse. Other types of fuse structures can also be created giving the impression of re-writable fuses.

In the manufacturing process of the device, the chip manufacturer fuses the chip before the chip is assembled in the device. In this process, the chip manufacture can connect a power supply to a test point of the chip and send an over-current of power to fuse the chip. However, because the chip manufacturer typically manufactures the chip months before the device is assembled, early chip fusing can lead to complications in the device manufacturing process. For example, if the same chip/board combination is used for different device products, the company producing the devices has to predict the market demand for each distinct devices months before the devices are produced. As another example, device manufacturing problems can arise, such as low production yields. If the device is being produced with debug access disabled, a specially manufactured set of chips that are fused to enable debug would be needed to provide chip debug access to aid in discovering the root of the manufacturing problem. Furthermore, if a new minimum software is needed to be enforced by a fused chip, a new set of fused chips will need to be manufactured to support the new minimum software. In the last two examples months of delay could result as the device manufacturer waits for the properly fused chips to be produced.

### SUMMARY OF THE DESCRIPTION

A process and apparatus for late fusing a device chip in a manufacturing process is described. In an exemplary process, a device is manufactured by assembling a chip onto a printed circuit board or substrate and the chip is fused (or otherwise configured) from power routed across the board to the chip. The power source for the fuse configuring can be generated from the internal power supply on the board or received on a test point on the board itself or a connection interface coupled to the board. In an exemplary apparatus, a device comprises a chip (e.g. an integrated circuit (IC)) and a board coupled to the chip, with the chip having a plurality of fuses that are used to configure the device and the board capable of routing power from the board to the chip. Furthermore, the power is used to blow one or more of the plurality of fuses. In one embodiment, the fuses are configured after the chip (or set of chips) has been attached to a printed circuit substrate which is the final substrate on which the chip (or set of chips) will reside when sold to a consumer. The board may be a main motherboard, implemented as a printed circuit board (PCB), of the device. In one embodiment, the fuses may be configured, among other things, to set a device's production mode, to set a debug access state, to set a security domain or other security features (such as a secure boot method), to set a state of user privileges, to set a state of a minimum required software (such as minimum software version number(s)), to set a state of allowable actions or software which can be run, or to set other features of the device; it will be understood that the fuses may be configured to provide one or more of these states or features or modes.

### BRIEF DESCRIPTION OF THE DRAWINGS

The present invention is illustrated by way of example and not limitation in the figures of the accompanying drawings in which like references indicate similar elements.

FIG. 1 is a block diagram of a device assembled with a chip that includes fuses.

FIG. 2 is a flow diagram of one embodiment of a process to configure one or more fuses of an assembled chip on a board of the device.

FIG. 3 is a flow diagram of one embodiment of a process to configure one or more fuses from different power sources.

FIG. 4AB are block diagrams of external power sources used to configure fuses on a chip.

FIG. 5 is a block diagram of different fuses available on a chip.

FIG. 6 is a flow diagram of one embodiment of a method to securely boot a device using the fuses on a chip of the device.

FIG. 7 illustrates one example of a typical computer system which may be used in conjunction with the embodiments described herein.

FIG. 8 shows an example of a data processing system which may be used with one embodiment of the present invention.

### DETAILED DESCRIPTION

A method and an apparatus for late fusing to support securely booting a device is described. In the following description, numerous specific details are set forth to provide thorough explanation of embodiments of the present invention. It will be apparent, however, to one skilled in the art, that embodiments of the present invention may be practiced without these specific details. In other instances, well-known components, structures, and techniques have not been shown in detail in order not to obscure the understanding of this description.

Reference in the specification to “one embodiment” or “an embodiment” means that a particular feature, structure, or characteristic described in connection with the embodiment can be included in at least one embodiment of the invention. The appearances of the phrase “in one embodiment” in various places in the specification do not necessarily all refer to the same embodiment.

The processes depicted in the figures that follow, are performed by processing logic that comprises hardware (e.g., circuitry, dedicated logic, etc.), software (such as is run on a general-purpose computer system or a dedicated machine), or a combination of both. Although the processes are described below in terms of some sequential operations, it should be appreciated that some of the operations described may be performed in different order. Moreover, some operations may be performed in parallel rather than sequentially.

The term “host” and the term “device” are intended to refer generally to data processing systems rather than specifically to a particular form factor for the host versus a form factor for the device.

In one embodiment, a device is fused late in the manufacturing process by configuring one or more fuses of a chip that is assembled onto a printed circuit substrate such as a board of the device. Late fusing the device gives the device producer flexibility in responding to market demand for the device, potential manufacturing problems, requiring a minimum software version running on the device, etc. In one embodiment, the device is manufactured by assembling the chip onto the board of the device. The device can optionally be further assembled by coupling a connection interface to the board and/or enclosing the board in a physical enclosure. The fuses of the partially or fully assembled device can be configured by applying power on a test point on the board or via the connection interface of the device. Alternatively, the device can generate the power internally that is used to configure the fuses.

According to one embodiment, the board of the device is capable of receiving and routing the power used to configure the fuses of the chip. The board comprises power routes that allow routing of power from the board test point, connection interface, and/or internal power supply to the chip. The fuses may be implemented in any one of a variety of hardware types; for example, a fuse may be a wire which can be melted with electrical current sent through the wire or with a laser or the fuse can be a set of electrical gates (e.g. transistors) which can be set in one of the two states. This power used to configure the fuses can be a normal operating current or an excessive current. These fuses are configured (usually irreversibly configured) after attaching, electrically and mechanically, the IC (chip) containing the fuses onto a circuit substrate such as a printed circuit board (PCB), which circuit substrate is included in the final device sold or otherwise transferred to a consumer.

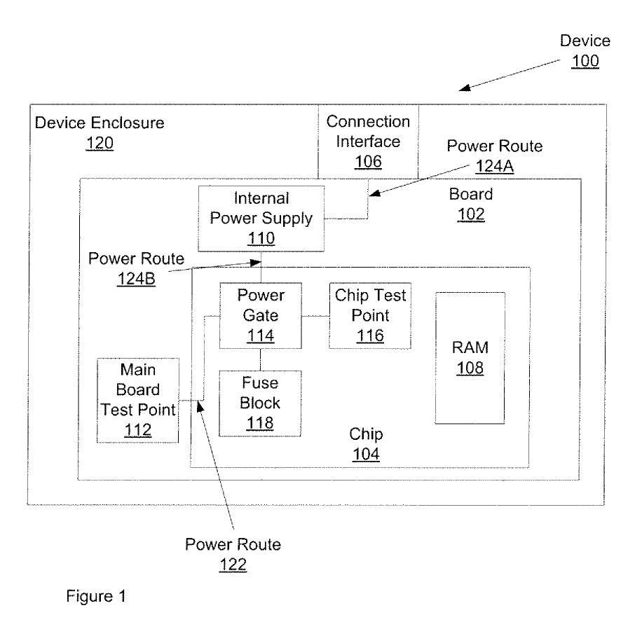

FIG. 1 is a block diagram of a device 100 assembled with a chip that includes fuses. In one embodiment, device 100 may be a mobile device such as a media player, a cellular telephone, notebook computer, global positioning system, personal digital assistant, etc. Alternatively, device 100 can be another type of device that can benefit from chip fusing, such as a computer, embedded device, etc. In FIG. 1, device 100 comprises board 102 within an enclosure 120. In one embodiment, board 102 may be a main motherboard, implemented as a printed circuit board (PCB), of the device. Coupled to board 102 and enclosure 120 is connection interface 106. Connection interface 106 may be based on a Universal Serial Bus (USB) connection, an Ethernet connection, a wireless network connection (e.g., IEEE 802.11x), etc. In one embodiment, connection interface 106 is used to transfer data between device 100 and a computer or other device coupled to device 100 via this interface. In another embodiment, connection interface 106 can provide power to device 100 via one or more of the pins that comprise connection interface 106. In one embodiment, connection interface 106 can provide power used to recharge a battery used by device 100. Enclosure 120 is a physical box or other shape used to enclose and protect the internal components of device 100. Once device 100 is assembled in enclosure 120, access to internal test points, such as board test point 112 and chip test point 116, can be disabled. In one embodiment, board 102 is the primary board used to interconnect the internal components of device 100. Board 102 further comprises chip 104, internal power supply 110, and board test point 112. In one embodiment, board 102 is engineered to handle and route the power to chip 104 that is used to configure the fuses.

Chip 104 can be any type of chip used in device 100, such as a central processing unit (CPU), a system on a chip (SoC), etc. Chip 104 comprises, in one embodiment, random access memory (RAM) 108, power gate 114, and fuse block 118. RAM 108 is one of a type of memory known in the art and is used by chip 104 to store software (not shown) that runs on chip 104. In one embodiment, the software is used by chip 104 to control the configuring of the individual fuses in fuse block. 118. In one embodiment, chip 104 further includes chip test point 116 that is a point on the chip 104 that can be used to introduce power directly into chip 104. This power can be used to configure the fuses during the manufacturing process of chip 104.

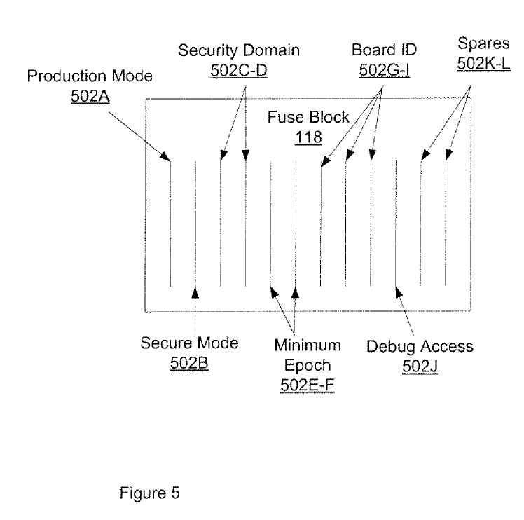

Fuse block 118 comprises one or more fuses that are used to permanently configure device 100. The type and number of fuses is further illustrated in FIG. 5 below. Configuring of the one or more fuses in fuse block 118 is controlled by software running on chip 104 using power gate 114. In one embodiment, power gate 114 comprises one gate coupled to each of the individual fuses in fuse block 118. In this embodiment, the software running on chip 104 sets each gate to either open or closed depending on whether the corresponding fuse is to be configured. An open gate allows the power routed from the board 102 or chip test point 116 to configure the corresponding fuse in fuse block 1.18. Conversely, a closed gate prevents power from flowing onto the corresponding fuse. In one embodiment, once a fuse is configured, the fuse is permanently set in the configured state and cannot be changed back to an unblown state.

Power to configure the fuses in fuse block 118 can come from different sources coupled to board 102. In one embodiment, device 100 routes power received at board test point 112 via power route 122 to power gate 114. In another embodiment, device 100 routes power received from connection interface 106 via power routes 124A-B through internal power supply 110 to power gate 114. Alternatively, power can be routed directly from connection interface 106 to power gate 114 via another power route (not shown). In a further embodiment, device 100 routes power generated from the internal power supply 110 to power gate 114 via power route 124B. In one embodiment, internal power supply 110 is a battery, or other component known in the art that is used to supply power to device 100.

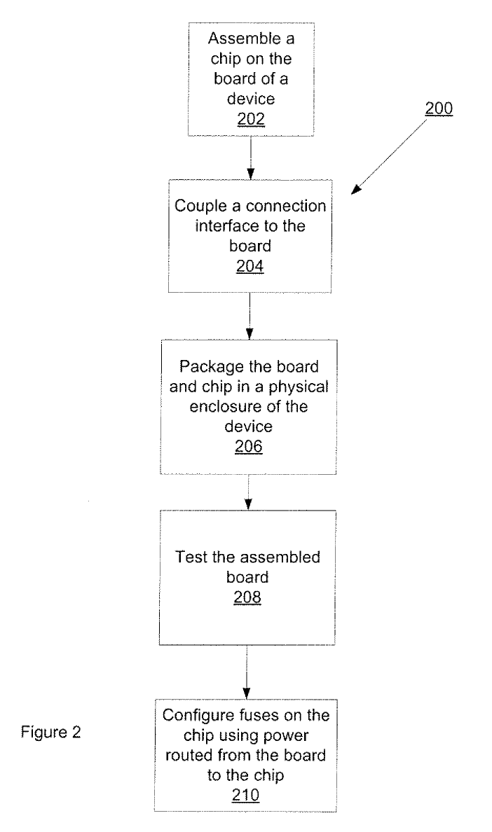

Because device 100 can accept, handle and route power used to configure the fuses from the board 102 to chip 104, a manufacturer can configure the fuses late in the device manufacturing process. As used hereinafter, late in the manufacturing process, or “late fusing,” means that the chip 104 fuses are configured after chip 104 is assembled onto board 102. This can include fusing the chip in a device that is partially or fully assembled. By late fusing the device, the device manufacturer can have quick turnarounds for fusing different chip/board combinations, enabling debug access in manufactured devices and/or requiring a new minimum software on the device. FIG. 2 is a flow diagram of one embodiment of a process 200 to configure, one or more fuse of an assembled chip on a board of the device. In one embodiment, the device manufacturer performs process 200 to configure the fuses for device 100 after chip 104 has been assembled onto board 102. In FIG. 2, at block 202, process 200 assembles a chip on the board of a device, such as device 100. In one embodiment, process 200 assembles a chip that has all or some of the fuses zeroed, or in the unconfigured state. In this embodiment, process 200 can configure one or more of the fuses after the chip is assembled on the board.

In another embodiment, the chip includes fuses that are all zeroed. In this embodiment, the device is inoperable in this fuse configuration using the device production software. The device production software is software used by the device for the device's intended purpose. For example, if the device is intended to be a portable music player, the device production software is software that enables the device to operate as a portable music player. Furthermore, in this embodiment, after configuring the fuses, the device is operable using the device production software. Alternatively, the device is operable using the device production software.

At block 204, process 200 can optionally further assemble the device by coupling a connection interface to the board of the device. In one embodiment, process 200 couples connection interface 106 to board 102 and power route 124A as illustrated in FIG. 1 above. In this embodiment, process 200 can configure the fuses of the chip either applying power to the board test point or the connection interface.

Process 200 can optionally further assemble the device by packaging the board with the assembled chip in the device enclosure at block 206. Furthermore, process 200 can couple the internal power supply to the board. In one embodiment, process 200 encloses board 102 and internal power supply 110 in physical enclosure 120. In this embodiment, process 200 can configure the fuses via the connection interface of the device or using the internal power supply.

At block 208, process 200 optionally tests the assembled device. In one embodiment, process 200 tests the assembled board by determining which fuses are currently in the fused state. In this embodiment, process 200 compares the configured fuses on the tested chip with the fuses expected to be configured at this point in the manufacturing process. For example, in one embodiment, process 200 determines which of the chips have configured fuses when expecting each chip to have no fuses configured. In this embodiment, the device manufacturer can check the chip production against a known chip configuration.

In one embodiment, test software is used to test the assembled device. In this embodiment, the test software is software that is different from the device production software and runs on the device with the fuses of the chip zeroed. In an alternate embodiment, process 200 tests the device using the device production software.

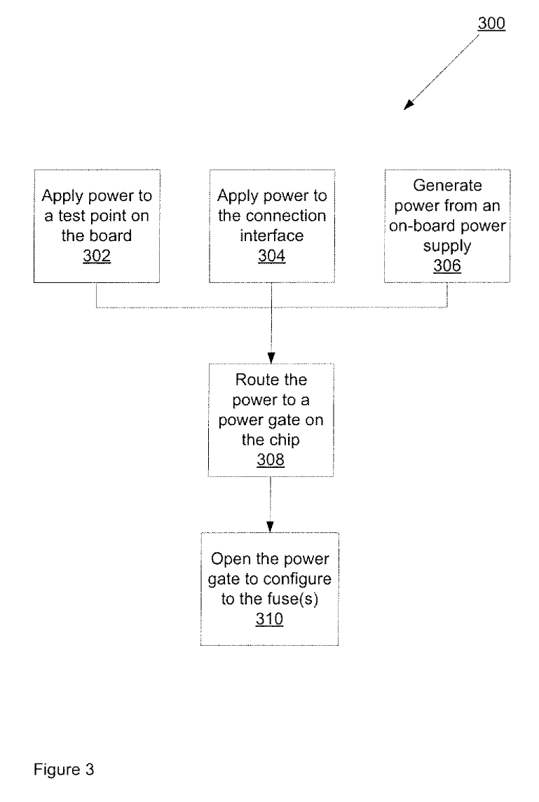

Process 200 configures one or more of the chip fuses in the assembled device at block 210. Process 200 can utilize one or more different ways to blow the fuses on the chip within the assembled device, such as applying power to a test point on the board, applying power to the connection interface of the device and/or having the internal power supply generate the power used to blow the fuse. Configuring the chip fuses is further described in FIG. 3 below.

FIG. 3 is a flow diagram of one embodiment of a process 300 that represents the processing of FIG. 2, block 210. In FIG. 3, one of three possible embodiments can be used by process 300 to supply the power used to configure the fuses. Different ones of these embodiments can be used depending on the assembled state of the device.

At block 302, in one embodiment, process 300 applies power to a test point on the board in which this power is used to configure the fuses. In this embodiment, process 300 applies power to the test point on the board, such as test point 312 on board 102 as illustrated in FIG. 1 above. This embodiment can be used when there is access to the board test point, for example, when the chip is assembled on the board but before the board is assembled into the physical enclosure. In an alternate embodiment, there is access to the board test point after the board is assembled into the physical enclosure and process 300 can apply power to the board test point after the board is assembled into the physical enclosure.

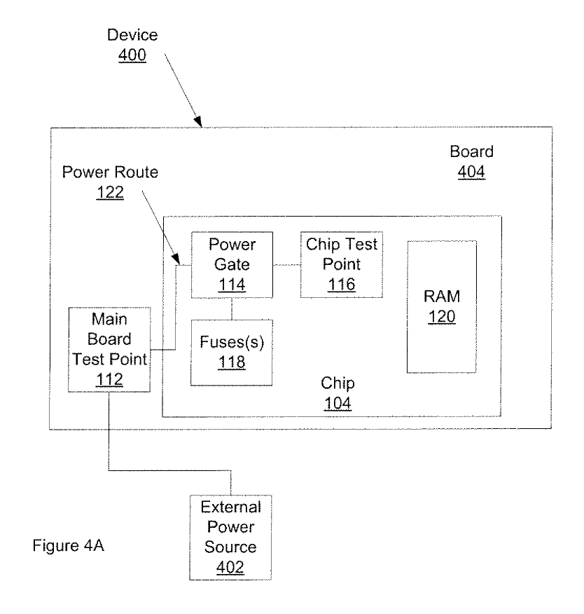

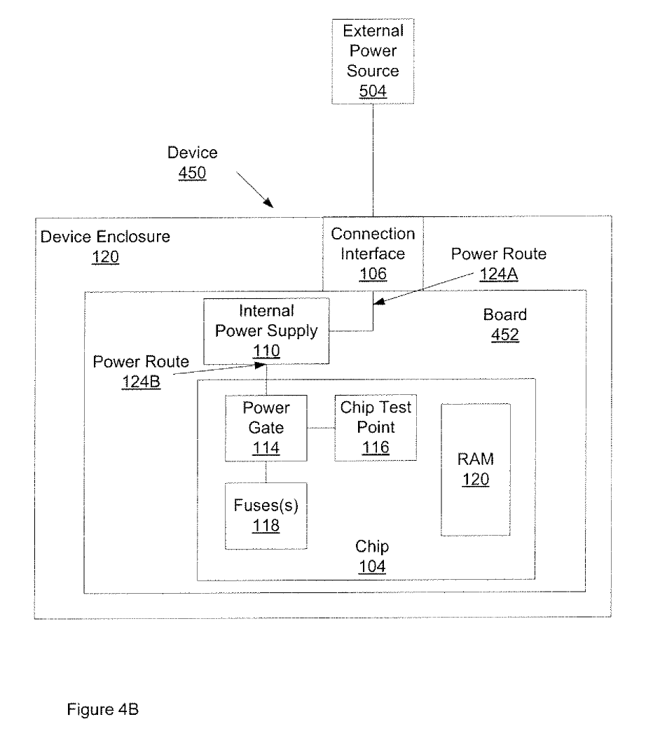

FIG. 4A is a block diagram of one embodiment that applies power to the board test point. In FIG. 4A, partially assembled device 400 comprises board 404 with chip 104. Board 404 further includes board test point 112 and power route 122. Chip 104 includes power gate 114, chip test point 116, fuse block 118 and RAM 120. In one embodiment, board test point 112, power route 122, and chip 104 are the same as in FIG. 1.

In order to supply the power used to configure fuses in fuse block 118, process 300 applies power using external power source 402 coupled to board test point 112. In one embodiment, the device manufacturer couples the partially assembled board to the external power supply in a testing rig. This rig can include one or more partially assembled boards.

Returning to FIG. 3, in another embodiment, at block 304, process 300 applies the power to the connection interface that is coupled to the board. For example, process 300 can apply power to connection interface 106 that is coupled to board 102 as illustrated in FIG. 1 above. This embodiment can be used when the connection interface is assembled onto the board. In addition, as the connection interface is typically exposed after the board is assembled into the physical enclosure, this embodiment can be used to supply the power used to configure the fuses after the physical enclosure is assembled onto the device.

FIG. 4B is a block diagram of one embodiment that applies power to the connection interface of the device. In FIG. 4B, device 450 comprises board 452 with chip 104. Board 452 further includes internal power supply 110 and power route 124B coupling internal power supply 110 and power gate 114. Board 452 is further coupled to connection interface 106. Power route 124A routes power from external power source 454 and connection interface 106 to internal power supply 110. Power route 124B further routes power from internal power supply 110 to power gate 114. Chip 104 includes power gate 114, chip test point 116, fuse block 118 and RAM 120. In one embodiment, connection interface 106, power routes 124A-B, and chip 104 are the same as in FIG. 1.

In order to supply the power used to configure the fuses in fuse block 118, process 300 applies power using external power source 454 coupled to connection interface 106. In one embodiment, the device manufacturer couples the device to the external power supply in a testing rig. This rig can include one or more devices.

Returning to FIG. 3, in another embodiment, at block 306, process 300 generates the power to configure the fuses from an on-board internal power supply, such as power supply 110 on board 102. This embodiment can be used before or after the board is assembled into the physical enclosure. In this embodiment, the internal power supply can generate the current needed to configure the fuses.

At block 308, process 300 routes the power from the power source across the board to a power gate on the chip. In one embodiment, process 300 routes the power from one or more of the power inputs, such as test point 112, connection interface 106, and/or internal power supply 110 to power gate 114. In one embodiment, one power source is used. Alternatively, multiple power sources could be used, including optionally in conjunction with power from chip test point 116. In one embodiment, device 100 uses process 300 to route power generated or received on the board to power gate 114 using power routes 122 and/or 124A-B as described in FIG. 1 above.

Process 300 configures the fuses using the power gate at block 310. In one embodiment, process 300 controls the one or more individual gates that control power admission to the individual fuses in the fuse block. For example, process 300 sets the individual gate to either open or closed depending on which fuse(s) are to be configured in fuse block 118 as described in FIG. 1 above.

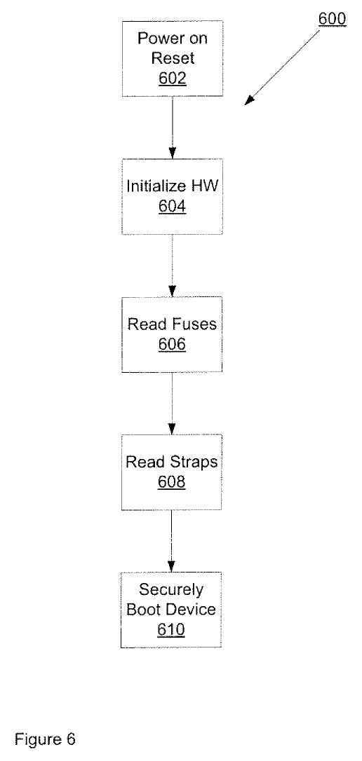

FIG. 5 is a block diagram of a fuse block with different fuses available on a chip. In FIG. 5, fuse block 118 comprises fuses 502A-L. The secure boot process as described in FIG. 6 below evaluates each of these fuses. In one embodiment, the secure boot process evaluates the fuses and configures the device accordingly.

Fuses 502A-L can be used individually or grouped together for device configuration purposes. In one embodiment, fuses 502A-L are grouped into different groups of fuses for a protection mode fuse 502A, security mode fuse 502B, security domain fuse 502C-D, minimum epoch fuses 502E-F, board ID fuses 502G-I, debug access fuse 502J, and spare fuses 502K-L. Furthermore, fuses can also be nested to allow a fuse to be re-written a pre-determined number of times. Fuse block 118 can have more or less fuses and these fuses can be grouped in the same or different manner. In one embodiment, production mode fuse 502A indicates whether the device should use production or development security behaviors. For example, if the development security behavior is set in this fuse, development security certificates stored in the device storage can be used. Alternatively, with the production security set with this fuse, production security certificates are used. Furthermore, in one embodiment, configuring this fuse to the production security behavior can override the setting of other fuses. For example, configuring fuse 502A to production security behavior disables debug access and overrides the setting of debug access fuse 502J.

Secure mode fuse 502B changes the behavior of the secure boot process to allow/disallow debugging and enable test modes that bypass trust evaluation. In one embodiment, this function of debugging access and test modes can be disabled by the appropriate setting of either the secure mode fuse 502B or the production mode fuse 502A.

Security domain fuses 502C-D selects which domain the device software must match to be trusted. In this embodiment, two fuses allows for up to four security domains. For example, the first security domain can be reserved for the chip manufacturer, such as the manufacturer of chip 104. In one embodiment, the manufacturer has its own certificates and keys corresponding to the manufacturer's security domain. Access to those keys, whether directly or indirectly, allows the manufacturer to sign code that can be run trusted on the manufacturer's security domain. For example, a system on a chip manufacturer might use the keys to sign test code that runs during the system on a chip testing. As another example, the contract manufacturer could use the keys to sign their test and diagnostic code.

The second security domain is reserved for the device when run by certain software. Other security domains can be reserved for other software efforts and/or other security control. In one embodiment, security domains seek to separate security responsibility and vulnerabilities in different software and/or hardware products. Different design teams could use different security domains. In addition, a single design team that develops products that are fundamentally different could use different security domains to achieve separation. Alternative embodiments can use more or less fuses for security domain.

Minimum epoch fuses 502E-F is used to prevent previously released software from being trusted on a newly manufactured device. In one embodiment, the device boots off trusted software and does not boot using untrusted software. In this embodiment, software with an epoch less than the minimum one required is considered untrusted. For example, previously released software may contain a severe security exploit. By requiring a minimum software epoch through fuses, this previously release software will not be able to run the device.

Board ID fuses 502G-I allow a large number of products to use the same chip/board combination and require different software builds. On one embodiment, each of the board ID fuses 502G-I add extra significant bits to the board ID straps. In one embodiment, board ID straps can be pins that are either dedicated or shared with other functions that allow the board designed to specify part of the board ID. The board ID from the fuses and the board ID from the pins arc concatenated to create the number the secure boot process uses as the board ID. This allows the large number of possible products from the same chip/board combination without requiring a large number of external straps. Furthermore, board ID fuses 502G-I allow different product teams flexibility in sharing parts. For example, if a single contract manufacturer produces two products for a company that used the same system on a chip hardware modulo fusing, the manufacturer would stock a number of parts to meet the predicted need of both the products instead of two separate stocks of parts. If on a given day more of one product and less of another were demanded, that larger demand could be met even if that demand exceeded the day's predicted demand. After the boards were assembled, the boards are fused with the correct board ID fuses.

Debug access fuse 502J enables/disables debug access to the chip. In one embodiment, debug access fuse 502J enables/disables debug access to the internal state of the chip. In another embodiment, other fuses, such as the production mode fuse 502A described above, may override debug access fuse 502J. In addition to the fuse discussed above, fuse block 118 can include spare fuses 502K-L that are reserved for future configuration functionality that would be implemented by future device software.

As described above, a device can use the one or more fuses to aid in securely booting the device. FIG. 6 is a flow diagram of one embodiment of a method 600 to securely boot a device using the fuses on a chip of the device. In one embodiment, device 100 uses method 600 to securely boot using the fuses in fuse block 118 to configure device 100 on boot up. In FIG. 6, at block 602, method 600 powers on reset. In one embodiment, method 600 configures the chips registers such that the memory on the chip is mapped to zero for the chip reset vector. At block 604, method 600 initializes the device hardware. In one embodiment, method 600 initializes various hardware of the device, such as power gates, clock gates, clock trees, device busses, etc.

Method 600 reads the fuses at block 606. In one embodiment, method 600 reads fuses 502A-L in fuse block 118 and configures the device according to the fuse configuration. An example of fuse configuration is illustrated above at FIG. 5. At block 608, method 600 reads the device straps, saves the board ID and boot configuration. Furthermore, method 600 uses the boot configuration to generate a list of valid boot devices that are to be tried when booting the device.

Method 600 securely boots the device at block 610. In one embodiment, method 600 tries a boot device listed in the boot configuration by loading an image object from the boot device. If method 600 is able to load the image, method 600 attempts to evaluate the trust of loaded image. If the image is trustable, method 600 will relocate the loaded image to the chip memory and decrypt the loaded image if necessary.

Fusing the chip late in the manufacturing process allows the device manufacturer flexibility in producing the device as opposed to fusing the chip and then assembling the device. In one embodiment, the device manufacturer can produce a number of chip/board assemblies that can be used for different products. Because the chip fusing for each product is done late in the manufacturing cycle, the device manufacturer can decide late in the manufacturing cycle which product the chip/board assembly is manufactured for. This is useful because chips are typically produced months before the assembly of the final device. Fusing the chip at the chip manufacturer sets the chip for one or the other particular product. However, fusing the chip late in the manufacturing process allows the device manufacturer to manufacture products close in time to shipping the product instead of having to predict demand months ahead of time.

In addition, late fusing allows the device manufacturer to rapidly spin the software epoch on newly manufactured devices for previous or existing software on existing devices that may have serious security comprises. Because fusing can be done very late in production, even after the device has been fully assembled, a higher software epoch can be imposed on newly manufactured device days before shipping the device. In contrast, fusing the chip during chip manufacturing, a software epoch cannot be spun except for months ahead of shipping the manufactured device. Thus, a software vulnerability can be addressed quickly for a device by requiring a new minimum software epoch.

When manufacturing a device, a manufacturer typically has to produce quantities of the device months before releasing the device. During this time, manufacturing problems can arise. For example, manufacturing yields may drop. In addition, typical devices manufactured for sale will have debug access turned off. With debug access turned off, it is difficult to determine causes of the manufacturing problems. By using late fusing, in one embodiment, the manufactured device can be fused for debug access after manufacturing. In another embodiment, a special batch of devices can be fused for debug access without producing a special batch of debug access chips as would have been done without late fusing. This allows the device development team to quickly diagnose the manufacturing problems using the debug access of the fused devices without having to wait months for a special batch of fused chips.

Furthermore, by fusing late in the manufacturing process, the manufacturer can run special software that only runs on a chip/board assembly with the chip fuses set in the unfused position. This would allow the manufacturer to run special test software instead of relying on special software builds from the device developer that would run on the fused chip.

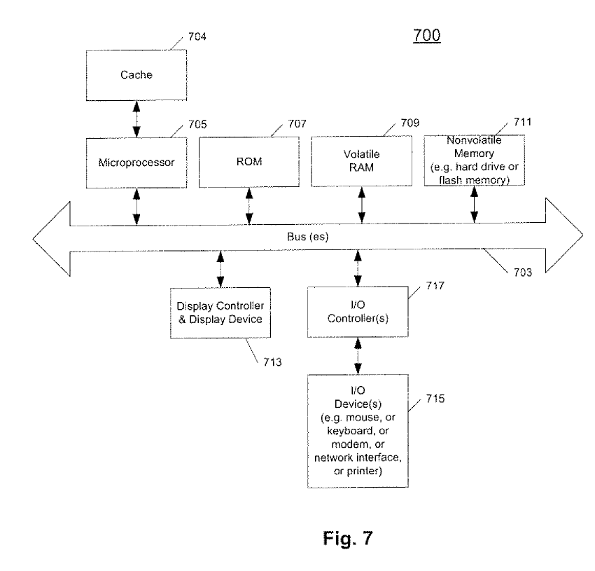

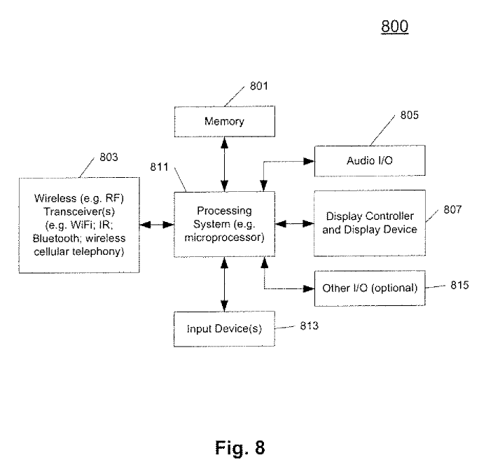

FIG. 7 shows one example of a data processing system, which may be used with one embodiment of the present invention. For example, the system 700 may be implemented including a host as shown in FIG. 8. Note that while FIG. 7 illustrates various components of a computer system, it is not intended to represent any particular architecture or manner of interconnecting the components as such details are not germane to the present invention. It will also be appreciated that network computers and other data processing systems or other consumer electronic devices which have fewer components or perhaps more components may also be used with the present invention.

As shown in FIG. 7, the computer system 700, which is a form of a data processing system, includes a bus 703 which is coupled to a microprocessor(s) 705 and a ROM (Read Only Memory) 707 and volatile RAM 709 and a non-volatile memory 711. The microprocessor 705 may retrieve the instructions from the memories 707, 709, 711 and execute the instructions to perform operations described above. The bus 703 interconnects these various components together and also interconnects these components 705, 707, 709, and 711 to a display controller and display device 713 and to peripheral devices such as input/output (I/O) devices which may be mice, keyboards, modems, network interfaces, printers and other devices which are well known in the art. Typically, the input/output devices 715 are coupled to the system through input/output controllers 717. The volatile RAM (Random Access Memory) 709 is typically implemented as dynamic RAM (DRAM) which requires power continually in order to refresh or maintain the data in the memory.

The mass storage 711 is typically a magnetic hard drive or a magnetic optical drive or an optical drive or a DVD RAM or a flash memory or other types of memory systems which maintain data (e.g. large amounts of data) even after power is removed from the system. Typically, the mass storage 711 will also be a random access memory although this is not required. While FIG. 7 shows that the mass storage 711 is a local device coupled directly to the rest of the components in the data processing system, it will be appreciated that the present invention may utilize a non-volatile memory which is remote from the system, such as a network storage device which is coupled to the data processing system through a network interface such as a modem, an Ethernet interface or a wireless network. The bus 703 may include one or more buses connected to each other through various bridges, controllers and/or adapters as is well known in the art.

FIG. 8 shows an example of another data processing system which may be used with one embodiment of the present invention. For example, system 800 may be implemented as part of system as shown in FIG. 1. The data processing system 800 shown in FIG. 7 includes a processing system 811, which may be one or more microprocessors, or which may be a system on a chip integrated circuit, and the system also includes memory 801 for storing data and programs for execution by the processing system. The system 800 also includes an audio input/output subsystem 805 which may include a microphone and a speaker for, for example, playing back music or providing telephone functionality through the speaker and microphone.

A display controller and display device 807 provide a visual user interface for the user; this digital interface may include a graphical user interface which is similar to that shown on a Macintosh computer when running OS X operating system software. The system 800 also includes one or more wireless transceivers 803 to communicate with another data processing system, such as the system 700 of FIG. 7. A wireless transceiver may be a WiFi transceiver, an infrared transceiver, a Bluetooth transceiver, and/or a wireless cellular telephony transceiver. It will be appreciated that additional components, not shown, may also be part of the system 800 in certain embodiments, and in certain embodiments fewer components than shown in FIG. 8 may also be used in a data processing system.

The data processing system 800 also includes one or more input devices 813 which are provided to allow a user to provide input to the system. These input devices may be a keypad or a keyboard or a touch panel or a multi touch panel. The data processing system 800 also includes an optional input/output device 815 which may be a connector for a dock. It will be appreciated that one or more buses, not shown, may be used to interconnect the various components as is well known in the art. The data processing system shown in FIG. 7 may be a handheld computer or a personal digital assistant (PDA), or a cellular telephone with PDA like functionality, or a handheld computer which includes a cellular telephone, or a media player, such as an iPod, or devices which combine aspects or functions of these devices, such as a media player combined with a PDA and a cellular telephone in one device or an embedded device or other consumer electronic devices. In other embodiments, the data processing system 800 may be a network computer or an embedded processing device within another device, or other types of data processing systems which have fewer components or perhaps more components than that shown in FIG. 8.

At least certain embodiments of the inventions may be part of a digital media player, such as a portable music and/or video media player, which may include a media processing system to present the media, a storage device to store the media and may further include a radio frequency (RF) transceiver (e.g., an RF transceiver for a cellular telephone) coupled with an antenna system and the media processing system. In certain embodiments, media stored on a remote storage device may be transmitted to the media player through the RF transceiver. The media may be, for example, one or more of music or other audio, still pictures, or motion pictures.

The portable media player may include a media selection device, such as a click wheel input device on an iPod® or iPod Nano® media player from Apple, Inc. of Cupertino, Calif., a touch screen input device, pushbutton device, movable pointing input device or other input device. The media selection device may be used to select the media stored on the storage device and/or the remote storage device. The portable media player may, in at least certain embodiments, include a display device which is coupled to the media processing system to display titles or other indicators of media being selected through the input device and being presented, either through a speaker or earphone(s), or on the display device, or on both display device and a speaker or earphone(s). Examples of a portable media player are described in published U.S. Pat. No. 7,345,671 and U.S. published patent number 2004/0224638, both of which are incorporated herein by reference.

Portions of what was described above may be implemented with logic circuitry such as a dedicated logic circuit or with a microcontroller or other form of processing core that executes program code instructions. Thus processes taught by the discussion above may be performed with program code such as machine-executable instructions that cause a machine that executes these instructions to perform certain functions. In this context, a “machine” may be a machine that converts intermediate form (or “abstract”) instructions into processor specific instructions (e.g., an abstract execution environment such as a “virtual machine” (e.g., a Java Virtual Machine), an interpreter, a Common Language Runtime, a high-level language virtual machine, etc.), and/or, electronic circuitry disposed on a semiconductor chip (e.g., “logic circuitry” implemented with transistors) designed to execute instructions such as a general-purpose processor and/or a special-purpose processor. Processes taught by the discussion above may also be performed by (in the alternative to a machine or in combination with a machine) electronic circuitry designed to perform the processes (or a portion thereof) without the execution of program code.

The present invention also relates to an apparatus for performing the operations described herein. This apparatus may be specially constructed for the required purpose, or it may comprise a general-purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), RAMs, EPROMs, EEPROMs, magnetic or optical cards, or any type of media suitable for storing electronic instructions, and each coupled to a computer system bus.

A machine readable medium includes any mechanism for storing or transmitting information in a form readable by a machine (e.g., a computer). For example, a machine readable medium includes read only memory (“ROM”); random access memory (“RAM”); magnetic disk storage media; optical storage media; flash memory devices; etc.

An article of manufacture may be used to store program code. An article of manufacture that stores program code may be embodied as, but is not limited to, one or more memories (e.g., one or more flash memories, random access memories (static, dynamic or other)), optical disks, CD-ROMs, DVD ROMs, EPROMs, EEPROMs, magnetic or optical cards or other type of machine-readable media suitable for storing electronic instructions. Program code may also be downloaded from a remote computer (e.g., a server) to a requesting computer (e.g., a client) by way of data signals embodied in a propagation medium (e.g., via a communication link (e.g., a network connection)).

The preceding detailed descriptions are presented in terms of algorithms and symbolic representations of operations on data bits within a computer memory. These algorithmic descriptions and representations are the tools used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be kept in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

The processes and displays presented herein are not inherently related to any particular computer or other apparatus. Various general-purpose systems may be used with programs in accordance with the teachings herein, or it may prove convenient to construct a more specialized apparatus to perform the operations described. The required structure for a variety of these systems will be evident from the description below. In addition, the present invention is not described with reference to any particular programming language. It will be appreciated that a variety of programming languages may be used to implement the teachings of the invention as described herein.

The foregoing discussion merely describes some exemplary embodiments of the present invention. One skilled in the art will readily recognize from such discussion, the accompanying drawings and the claims that various modifications can be made without departing from the spirit and scope of the invention.

1.-15. (canceled)

16. A device comprising:
a chip comprising a plurality of fuses that are used to configure the device; and
a circuit substrate coupled to the chip wherein the circuit substrate is capable of routing power from the circuit substrate to the chip during intended use of the device after manufacture and configuring of the device, wherein the circuit substrate also routes the power used by the chip to configure one or more of the plurality of fuses.

17. The device of claim 16, further comprising:
a test point on the circuit substrate, the test point, being capable of receiving the power.

18. The device of claim 16, further comprising:
a connection interface coupled to the circuit substrate, the connection interface being capable of receiving the power and routing the power to the circuit substrate,

19. The device of claim 18, wherein the connection interface is further capable of transferring data between the device and a computer and is further capable of providing power to recharge a battery of the device.

20. The device of claim 16, further comprising:
an internal power supply coupled to the circuit substrate capable of generating the power to configure the one or more fuses.

21. The device of claim 16, wherein each of the plurality of fuses can configure at least one of device type, production status, security domain, minimum software version number and debug access.

22. The device of claim 16, wherein each of the plurality of fuses is zeroed prior to the configuring of the one or more of the plurality of fuses.

23. The device of claim 22, wherein the device is inoperable using the device production software when the plurality of fuses is zeroed, wherein the device production software is capable of operating the device for its intended purpose.

24. The device of claim 22, wherein the chip is further capable of running test software that tests the device with the plurality of fuses zeroed.

25. The device of claim 16, wherein the circuit substrate is capable of configuring the one or more fuses by routing the power to a power gate on the chip coupled to the one or more fuses and opening the power gate to allow power to flow to the one or more fuses.

26. The device of claim 16, further comprising:
a physical enclosure coupled to the device, wherein the physical enclosure is coupled to the device before the one or more fuses are configured.

27. The device of claim 16, wherein the configuring of the one or more fuses includes configuring a fuse that indicates that a minimum software epoch is required for the device to be operable.

28. The device of claim 1.6, wherein the chip is a central processing unit.
